(19) United States
(12) Patent Application Publication
(10) Pub. No.: US 2017/0125070 A1
(43) Pub. Date: May 4, 2017

(54) SYSTEM AND METHOD FOR HIBERNATION USING A DELTA GENERATOR ENGINE

(71) Applicant: SanDisk Technologies Inc., Plano, TX (US)

(72) Inventors: Amir Hadar, Kfar-Saba (IL); Eli Menachem Elmoalem, Nili (IL); David Brief, Modiin (IL); Tzachy Yizhaki, Kfar-Saba (IL)

(21) Appl. No.: 14/926,896

(22) Filed: Oct. 29, 2015

(51) Int. Cl. G11C 5/14; G11C 14/00

(52) U.S. Cl. CPC G11C 5/148; G11C 14/00

(57) ABSTRACT

Apparatus and method for hibernating part of a memory device are disclosed. A memory device may seek to reduce its power consumption by entering deep power down (DPD) mode. In DPD mode, power to a section of volatile memory in the memory device may be removed. To that end, the memory device stores in non-volatile memory all of the data stored in the section of volatile memory. The data stored in non-volatile memory is accessed upon exiting DPD mode. Upon subsequent entries into DPD mode, a differential, between the data stored in non-volatile memory and the data currently stored in the section of volatile memory subject to power removal, is generated and stored in non-volatile memory. Upon exit of the DPD mode, the data stored in non-volatile memory and the differential are used to recreate the data stored in volatile memory at entry into DPD mode.

### TECHNICAL FIELD

This application relates generally to memory devices. More specifically, this application relates to using a delta generator engine to save data stored in volatile memory when hibernating the volatile memory.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A memory device may operate in one of several modes, such as a normal mode and a power save mode. When operating in the power save mode, the memory device may modify its operation from the normal mode in order to reduce power consumption by the memory device. Various power saving methods have benefits and drawbacks, including the amount of power saved and the time to reconfigure the memory device from the power save mode back to the normal mode.

### BRIEF DESCRIPTION OF THE DRAWINGS

The system may be better understood with reference to the following drawings and description. In the figures, like reference numerals designate corresponding parts throughout the different views.

FIG. 1A is a block diagram of an example non-volatile memory device.

FIG. 1B is a block diagram illustrating an exemplary storage circuitry.

FIG. 1C is a block diagram illustrating a hierarchical storage system.

FIG. 2A is a block diagram illustrating exemplary components of a controller of a non-volatile memory device.

FIG. 2B is a block diagram illustrating exemplary components of a non-volatile memory of a non-volatile memory storage system.

FIG. 3 illustrates a block diagram of the hibernation circuitry and different regions of memory.

FIG. 4A illustrates a block diagram of the data generation engine in generating, with the current data, the base data and the accumulated delta, and in recreating the current data.

FIG. 4B illustrates another block diagram of the data generation engine.

FIG. 5 illustrates a sequence of base datas and accumulated deltas stored over time.

FIG. 6 illustrates a flow chart for determining whether to store the base data and whether to store the delta.

FIG. 7 illustrates a first flow chart for determining whether and how to restore data previously stored in volatile memory.

FIG. 8 illustrates a second flow chart for determining whether and how to restore data previously stored in volatile memory.

### DETAILED DESCRIPTION

There are times when power is interrupted to volatile memory. As one example, a memory device may intentionally remove power from volatile memory (such as to a part or a section of volatile memory within the memory device), for example when transitioning from a normal mode into a low-power mode (or power-save mode). In one embodiment, the memory device may enter the low-power mode in response to a command from a host device. Alternatively, the memory device may enter low-power mode based upon its own determination.

In low-power mode, the memory device typically consumes less power than when operating in normal mode. One example of a low-power mode is deep power down (DPD) mode (also known as hibernation mode). Memory devices may enter DPD mode thousands of times per day, and millions of times in the life cycle of the memory device. Hence, significant power savings may result from the DPD mode.

In DPD mode, power to various parts of the memory device may be removed or reduced. For example, power may be removed to part or all of the volatile memory resident within the memory device. Volatile memory requires power to be maintained for the information stored within the volatile memory to be considered valid. In particular, the volatile memory retains the contents stored within while powered on. Prior to removing power from the volatile memory, the information stored therein may be stored elsewhere (such as in non-volatile memory or in volatile memory not subject to power removal), as discussed in more detail below.

In this regard, in the DPD mode, as much volatile memory (such as static random access memory (SRAM)) as possible in the flash controller is powered down, while ensuring proper and fast resumption of the flash controller operation after exiting DPD mode.

One approach is for the memory device to save its non-volatile memory content in non-volatile memory (e.g., in flash memory) each time DPD mode. In particular, the controller may store most or all of the RAM content (e.g., the system state including its program store and data store) prior to power down, and restore the content to RAM after power up. While this approach saves power, given that DPD mode is entered thousands of times per day, the flash memory endurance would be greatly reduced due to sheer usage. To mitigate the wear on flash memory, the RAM content may be compressed prior to saving to flash memory, potentially achieving about 50%-70% compression ratio, thereby reducing the amount of data needed to save to flash memory. Nevertheless, even with compression (which would include separate hardware compression circuitry), the amount of data is still very large, significantly reducing flash memory endurance.

Still another approach is, in response to determining to enter the DPD mode, the controller is configured to store part (but not all) of the data stored in a section of the volatile memory. In one embodiment, prior to the controller determining to enter the DPD mode (such as at time t₀), the controller stores part or all of the data that is stored in the section of volatile memory. In a more specific embodiment, the controller stores all of the data that is stored in the section of volatile memory into another section of memory (such as in non-volatile flash memory). In one embodiment, all of the data that is stored in the section of volatile memory may first be compressed and then stored into non-volatile flash memory. In an alternate embodiment, all of the data that is stored in the section of volatile memory may be stored uncompressed into non-volatile flash memory. As discussed in more detail below, one example of all of the data that is stored in the section of volatile memory is termed base data.

When the controller determines to enter the DPD mode (such as at time t₁), the controller stores part (but less than all) of a representation of the data that is stored at the current time (e.g., at time t₁). In a more specific embodiment, the representation that is stored is based on (and dependent on) a previous storage in preparation for entering DPD mode. In particular, the representation comprises a difference (e.g., a delta) between the base data and the data as currently stored in the section of memory. As discussed in more detail below, the controller, using a data generation engine, stores the delta between the base data and the current data as stored in the section of memory. Thus, in one embodiment, the delta is a representation of the data (but not the data itself), and is dependent on a previous storage of the data in the section of memory (e.g., the base data stored at a previous time). In this way, the base data is not an exact representation of the data stored in the volatile memory at the time of power loss (e.g., the base data represents the data stored in the volatile memory at a previous time); however, the base data and the delta combined reflect the data stored in the volatile memory at the time of power loss.

After entering DPD mode, the controller may exit DPD mode and restore the data as stored in the section of volatile memory when entering DPD mode. In particular, at time t₂ (which is later than both t₀ and t₁), the controller may receive a command from the host device to exit DPD mode. In response thereto, the controller recreates the data as stored in the section of volatile memory at the time that the DPD mode was entered (such as the data as stored in SRAM at time t₁). The controller may access multiple pieces of data, such as the base data and the delta, and using the accessed multiple pieces of data, recreate the data at the time that the DPD mode was entered.

The controller may trigger the storing of the base data in one of several ways. In one way, the trigger may be in response to initialization of the memory device. In another way, the trigger may be based on whether the memory device has additional time to generate the base data. In particular, the controller of the memory device may generate the base data when the controller is in idle mode, such as no pending writes of host data. In still another way, the trigger may be based on a state of the memory in which the base data is stored. For example, the base data may be stored in a block (or blocks) of memory. When the block (or blocks) are full and need to be erased, the controller may generate a new base data.

In yet another way, the trigger may be based on analysis of one or both of the delta and the base data. In particular, the size of the delta, the size of the base data, and/or the size of the delta and the base data may be analyzed. As one example, the size of the delta may be compared with a threshold. The threshold may be static or dynamic, and may be determined based on the endurance of the block storing the base data. For example, the threshold may be selected based on the calculated expected endurance from the block storing the base data (e.g., how many more writes are expected for the block used to store the base data). Heuristics may determine an expected number of times the host device may request a deep power down during the lifetime of the device, and may determine an expected number of writes for the life of the block used to store the base data. The threshold (used to determine the maximum size for the delta prior to regenerating the base data) may be selected in order not to exceed the endurance targeted for the block used to store the base data. In practice, if the threshold is larger (meaning that the delta may be of a larger size prior to regenerating the base data), then the block may be filled sooner, meaning that new blocks will be allocated more frequently, and in turn meaning that blocks will be worn more quickly. In this way, the threshold may be calculated in correlation with the expected endurance of this block.

As another example, the size of the delta may be compared with the size of the base data. If the size of the delta is greater than the size of the base data, the controller may determine to generate a new base data. As another example, the size of the delta and/or the size of the base data may be adjusted by a correction factor, and compared. In particular, the size of the base data may be adjusted by the correction factor, and compared with the size of the delta. If the size of the delta is greater than the adjusted size of the base data, the controller may determine to generate a new base data.

In an alternate embodiment, the memory device does not generate a base data. Instead, the base data is static in nature, and may be pre-programmed within the memory device, such as stored during manufacture of the memory device. As discussed in more detail below, the volatile memory subject to power down may comprise controller volatile memory. The controller may typically store certain types of data, such as global variables, data buffers, etc., in the controller volatile memory. In this way, the base data may comprise a typical values for the global variables, data buffers, etc., and be stored in read only memory (ROM).

In one embodiment, the base data and/or the delta are compressed with one or more compression algorithms. In an alternate embodiment, the base data and/or the delta are not compressed.

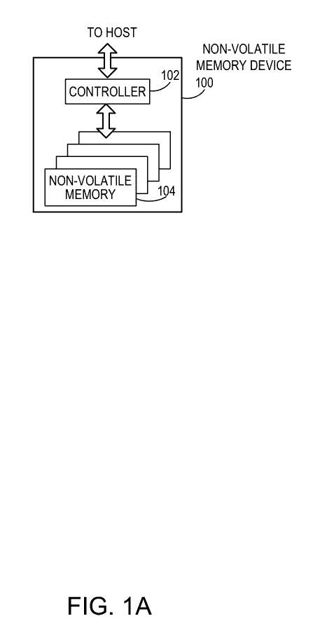

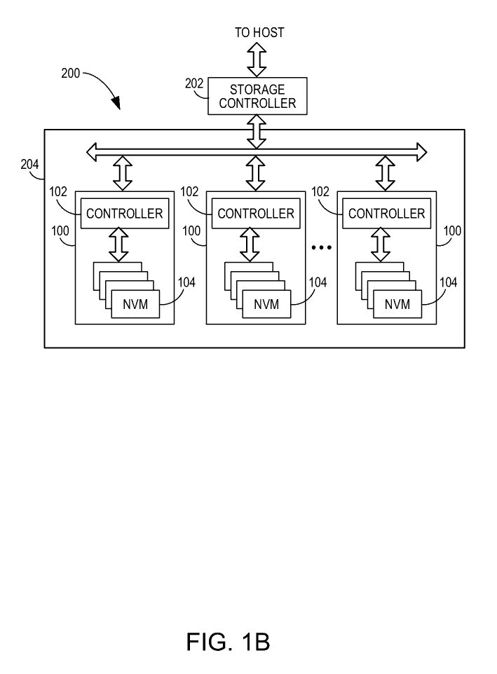

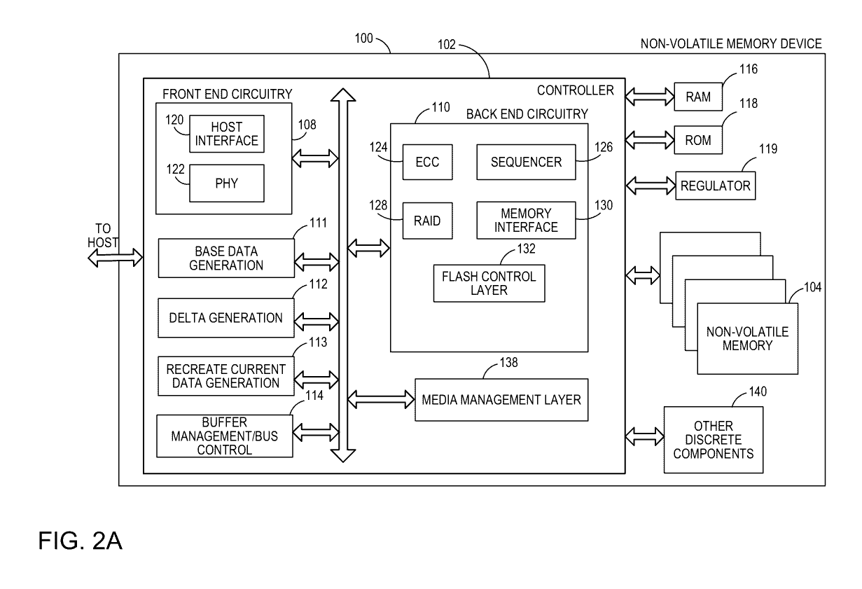

Referring to the figures, FIG. 1A is a block diagram illustrating a non-volatile memory device. The non-volatile memory device 100 includes a controller 102 and non-volatile memory that may be made up of one or more non-volatile memory die 104. The non-volatile memory die may comprise one or more memory integrated circuit chips. One or both of the controller 102 and non-volatile memory die 104 may use a regulated voltage. As used herein, the term die refers to the set of non-volatile memory cells, and associated circuitry for managing the physical operation of those non-volatile memory cells, that are formed on a single semiconductor substrate. Controller 102 interfaces with a host device and transmits command sequences for read, program (e.g., write), and erase operations to non-volatile memory die 104.

The controller 102 (which may in one embodiment be a flash memory controller) can take the form of processing circuitry, a microprocessor or processor, and a computer-readable medium that stores computer-readable program code (e.g., software or firmware) executable by the (micro)processor, logic gates, switches, an application specific integrated circuit (ASIC), a programmable logic controller, and an embedded microcontroller, for example. These examples of the controller 102 are not exhaustive and other forms for performing controller functionality are contemplated. The controller 102 can be configured with hardware and/or firmware to perform the various functions described below and shown in the flow diagrams. For example, the hardware and/or firmware may be configured for analysis of the incoming data stream (such as for bandwidth and/or consistency) and for determination whether to use hybrid blocks, as discussed in more detail below. Also, some of the components shown as being internal to the controller can also be stored external to the controller, and other components can be used. Additionally, the phrase “operatively in communication with” could mean directly in communication with or indirectly (wired or wireless) in communication with through one or more components, which may or may not be shown or described herein.

One type of controller 102 is a flash memory controller. As used herein, a flash memory controller is a device that manages data stored on flash memory and communicates with a host device, such as a computer or electronic device. A flash memory controller can have various functionality in addition to the specific functionality described herein. For example, the flash memory controller can format the flash memory to ensure the memory is operating properly, map out bad flash memory cells, and allocate spare cells to be substituted for future failed cells. Some part of the spare cells can be used to hold firmware to operate the flash memory controller and implement other features. In operation, when a host device seeks to read data from or write data to the flash memory, it will communicate with the flash memory controller. If the host device provides a logical address to which data is to be read/written, the flash memory controller can convert the logical address received from the host device to a physical address in the flash memory. (Alternatively, the host device can provide the physical address). The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 104 may include any suitable non-volatile storage medium, including NAND flash memory cells and/or NOR flash memory cells. One example of non-volatile memory die 104 may comprise a memory integrated circuit chip. The memory cells can take the form of solid-state (e.g., flash) memory cells and can be one-time programmable, few-time programmable, or many-time programmable. As discussed above, the memory cells can also be single-level cells (SLC), multiple-level cells (MLC), triple-level cells (TLC), quadruple-level cells (QLC), or use other memory cell level technologies, now known or later developed. Also, the memory cells can be fabricated in a two-dimensional or three-dimensional fashion.

The interface between controller 102 and non-volatile memory die 104 may be any suitable flash interface, such as Toggle Mode 200, 400, or 800. In one embodiment, memory device 100 may be a card based system, such as a secure digital (SD) or a micro secure digital (micro-SD) card. In an alternate embodiment, memory device 100 may be part of an embedded memory system.

Although in the example illustrated in FIG. 1A non-volatile memory device 100 includes a single channel between controller 102 and non-volatile memory die 104, the subject matter described herein is not limited to having a single memory channel. For example, in some NAND memory system architectures such as illustrated in FIGS. 1B-C, 2, 4, 8 or more NAND channels may exist between the controller and the NAND memory device, depending on controller capabilities. In any of the embodiments described herein, more than a single channel may exist between the controller and the memory die, even if a single channel is shown in the drawings.

FIG. 1B illustrates storage circuitry 200 that includes plural non-volatile memory devices 100. As such, storage circuitry 200 may include a storage controller 202 that interfaces with a host device and with storage system 204, which includes a plurality of non-volatile memory devices 100. The interface between storage controller 202 and non-volatile memory devices 100 may be a bus interface, such as a serial advanced technology attachment (SATA) or peripheral component interface express (PCIe) interface. Storage circuitry 200, in one embodiment, may be a solid state drive (SSD), such as found in portable computing devices, such as laptop computers, and tablet computers.

FIG. 1C is a block diagram illustrating a hierarchical storage system. A hierarchical storage system 250 includes a plurality of storage controllers 202, each of which controls a respective storage system 204. Host systems 252 may access memories within the hierarchical storage system via a bus interface. In one embodiment, the bus interface may be a non-volatile memory express (NVMe) or a fiber channel over Ethernet (FCoE) interface. In one embodiment, the system illustrated in FIG. 1C may be a rack mountable mass storage system that is accessible by multiple host computers, such as would be found in a data center or other location where mass storage is needed.

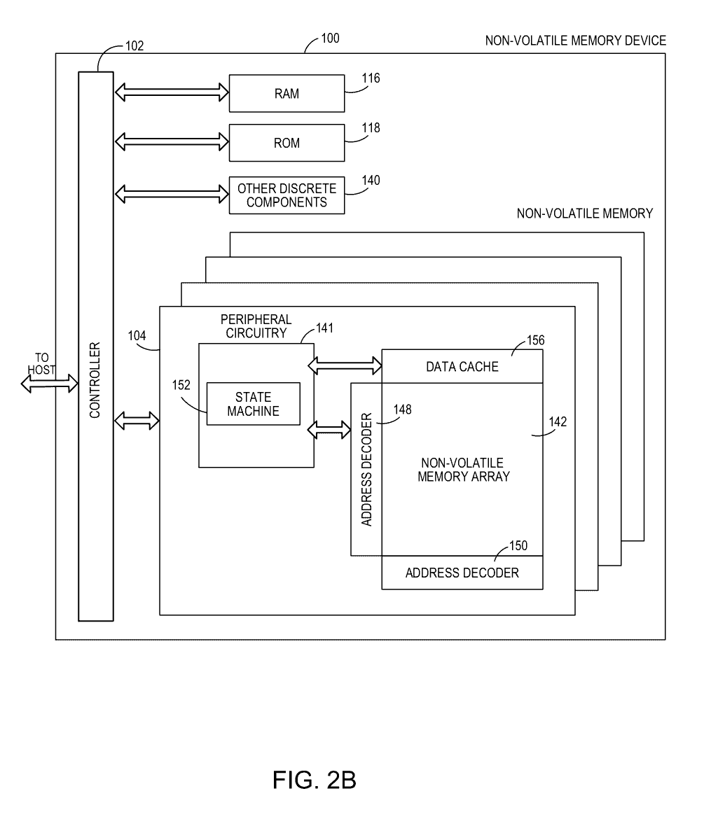

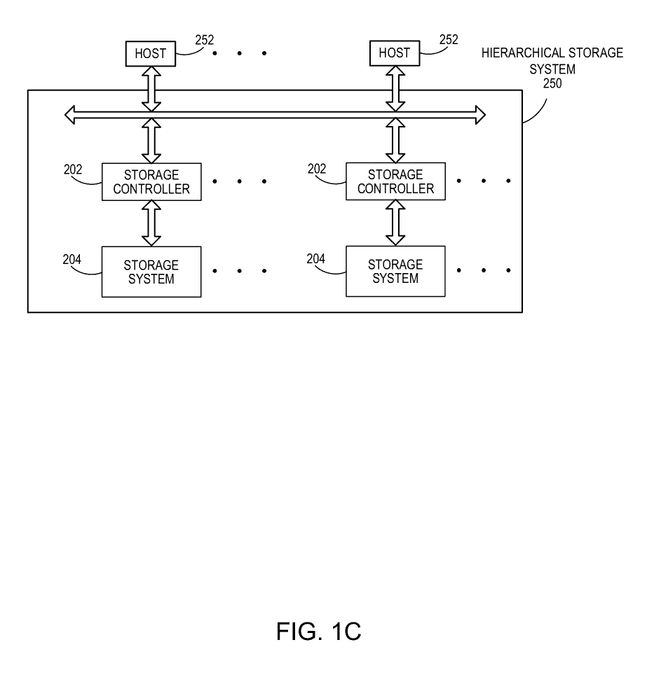

FIG. 2A is a block diagram illustrating exemplary components of controller 102 in more detail. Controller 102 includes a front end circuitry 108 that interfaces with a host device, a back end circuitry 110 that interfaces with the one or more non-volatile memory die 104, and various other circuitry that perform functions which will now be described in detail.

Circuitry of the controller 102 may include a base data generation circuitry 111, a delta generation circuitry 112, and a recreate current data generation circuitry 113. As explained in more detail below, the base data generation circuitry 111 may generate, at the time of generation, a complete set of values of data in a certain section of volatile memory. In particular, the controller 102 may determine whether to execute the base generation circuitry 111 in one of several ways, such as upon start-up of the memory device, upon a first entry into hibernation of the certain section of volatile memory, upon identification of an idle time, and/or upon other factors, discussed in more detail herein. In response to the controller 102 determining to execute the base generation circuitry 111, the controller 102 executes the base generation circuitry. In an alternative embodiment, the memory device does not include base generation circuitry 111. As discussed in more detail below, the memory device may have a static set of base data that does not change regardless of the data stored in the certain section of memory. In that instance, the static set of base data may be pre-programmed upon manufacture and may be used throughout the life of the memory device. In this embodiment, the memory device will not generate the base data, and need not include the base generation circuitry 111.

Further, as explained in more detail below, the delta generation circuitry 112 may generate, at the time of generation, a difference between the base data (indicative of the data stored in the certain section of memory at a previous time, such as time₀) and the data stored in the certain section of memory (at the time of generation, such as time₁, with time₁ being later in time than time₀). The controller 102 may determine whether to execute the delta generation circuitry 112 in one of several ways, such as in response to determining to power down the certain section of memory.

In addition, as explained in more detail below, the recreate current data generation circuitry 113 may recreate the data as stored in the volatile memory at a previous time using the base data and the delta generated by the delta generation circuitry 112. In the example above, the delta generation circuitry 112 generates the delta (e.g., the difference) for the data at time₁. Upon execution of recreate current data generation circuitry 113, the data may be recreated as stored in the volatile memory at time₁.

While in some implementations the base data generation circuitry 111, the delta generation circuitry 112, and the recreate current data generation circuitry 113 may be part of the controller 102, in other implementations, all or a portion of the base data generation circuitry 111, the delta generation circuitry 112, and the recreate current data generation circuitry 113 may be discrete components, separate from the controller 102, that interface with the controller 102.

Referring again to circuitry of the controller 102, a buffer manager/bus controller 114 manages buffers in random access memory (RAM) 116 and controls the internal bus arbitration of controller 102. A read only memory (ROM) 118 stores system boot code. Although illustrated in FIG. 2A as located separately from the controller 102, in other embodiments one or both of the RAM 116 and ROM 118 may be located within the controller. In yet other embodiments, portions of RAM and ROM may be located both within the controller 102 and outside the controller. Further, in some implementations, the controller 102, RAM 116, and ROM 118 may be located on separate semiconductor die.

Front end circuitry 108 includes a host interface 120 and a physical layer interface (PHY) 122 that provide the electrical interface with the host device or next level storage controller. The choice of the type of host interface 120 can depend on the type of memory being used. Examples of host interfaces 120 include, but are not limited to, SATA, SATA Express, SAS, Fibre Channel, USB, PCIe, eMMC I/F, and NVMe. The host interface 120 typically facilitates transfer for data, control signals, and timing signals.

Back end circuitry 110 includes an error correction controller (ECC) engine 124 that encodes the data bytes received from the host device, and decodes and error corrects the data bytes read from the non-volatile memory. A command sequencer 126 generates command sequences, such as program and erase command sequences, to be transmitted to non-volatile memory die 104. RAID (Redundant Array of Independent Drives) circuitry 128 manages generation of RAID parity and recovery of failed data. The RAID parity may be used as an additional level of integrity protection for the data being written into the non-volatile memory device 100. In some cases, the RAID circuitry 128 may be a part of the ECC engine 124. A memory interface 130 provides the command sequences to non-volatile memory die 104 and receives status information from non-volatile memory die 104. In one embodiment, memory interface 130 may be a double data rate (DDR) interface, such as a Toggle Mode 200, 400, or 800 interface. A flash control layer 132 controls the overall operation of back end circuitry 110.

Additional components of system 100 illustrated in FIG. 2A include media management layer 138, which performs wear leveling of memory cells of non-volatile memory die 104. System 100 also includes other discrete components 140, such as external electrical interfaces, external RAM, resistors, capacitors, or other components that may interface with controller 102.

In alternative embodiments, one or more of the physical layer interface 122, RAID circuitry 128, media management layer 138 and buffer management/bus controller 114 are optional components that are not necessary in the controller 102.

FIG. 2B is a block diagram illustrating exemplary components of non-volatile memory die 104 in more detail. Non-volatile memory die 104 includes peripheral circuitry 141 and non-volatile memory array 142. Non-volatile memory array 142 includes the non-volatile memory cells used to store data. The non-volatile memory cells may be any suitable non-volatile memory cells, including NAND flash memory cells and/or NOR flash memory cells in a two dimensional and/or three dimensional configuration. Peripheral circuitry 141 includes a state machine 152 that provides status information to controller 102.

Non-volatile memory die 104 further includes address decoders 148, 150 for addressing within non-volatile memory array 142, and a data cache 156 that caches data.

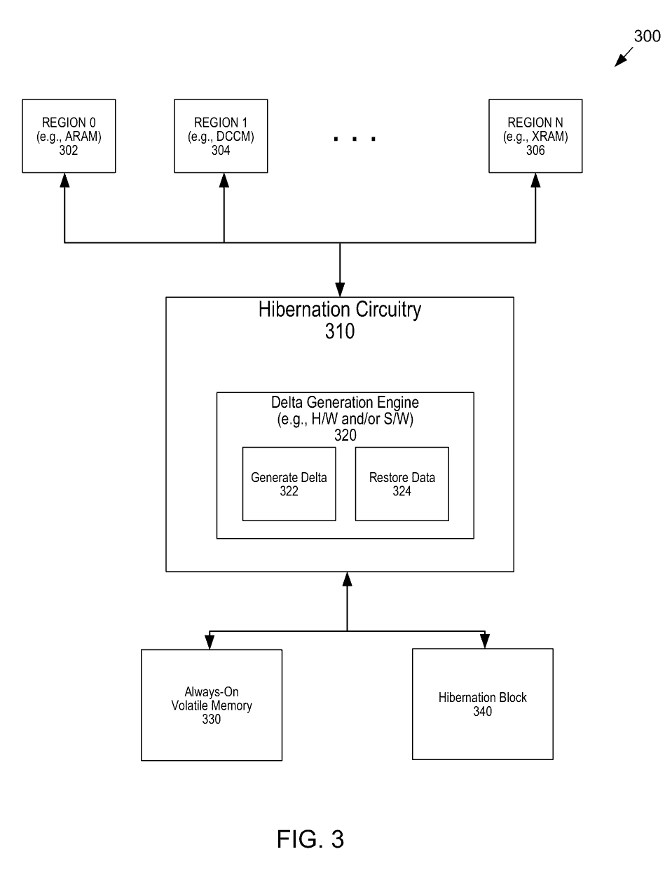

FIG. 3 illustrates a block diagram 300 of the hibernation circuitry 310 and different regions of memory. As shown in FIG. 3, different regions of memory include: region 0 302, which may comprise analog random access memory (ARAM); region 1 304, which may comprise data closely coupled memory (ARAM); to region N 306, which may comprise XRAM. The regions of memory and the number of regions illustrated in FIG. 3 are merely for illustration purposes. Other types of memory and different numbers of regions of memory are contemplated.

One, some or all of regions 302, 304, 306 may store data, such as global variables, data buffers, etc., that need to be maintained after exiting the DPD mode.

Hibernation circuitry 310 includes delta generation engine 320. In one embodiment, hibernation circuitry 310 may be implemented purely by firmware (F/W). In an alternate embodiment, hibernation circuitry 310 may be implemented by a combination of F/W and hardware (H/W). Hibernation circuitry 310 may use delta generation engine 320 to hibernate part or all of volatile memory in the memory device, such as one or more of region 0 (302), region 1 (304), . . . region N (306). As discussed below, hibernation circuitry 310, through various components therein, is configured to perform the following: generate delta for data stored in volatile memory (e.g., global variables and data buffers) upon entering a DPD mode; restore the data (e.g., global variables and data buffers) upon exiting the DPD mode; and maintaining one or more sections of memory (such as always-on volatile memory 330 and hibernation block 340) for storing the base data and the delta.

In one embodiment, Delta generation engine 320 is configured to compute the delta needed to be stored in hibernation block 340 when entering DPD mode, and to compute and restore the data, such as the global variables and data buffers, using the base data and the delta upon exiting a DPD mode. To that end, delta generation engine 320 includes generate delta circuity 322 and restore data circuitry 324, as discussed in more detail below. Generate delta circuitry 322 may be performed by F/W, or alternatively may be H/W assisted, such as with a dedicated XOR engine.

Restore data circuitry 324 may be used to restore the data in volatile memory. In particular, upon exiting DPD mode, restore data circuitry 324 may restore the data using delta and the base data.

Hibernation block 340 comprises a section of memory within memory device for storing part or all of the data related to hibernation. In one embodiment, hibernation block 340 comprises non-volatile memory, such as flash memory. In one embodiment, hibernation blocks stores the base data and part of the delta (to the extent there is insufficient space in always-on volatile memory 330). In particular, the delta generated on each DPD cycle may be fully stored in always-on volatile memory 330. In the event that delta is too large to store entirely in always-on volatile memory 330, part of the delta is stored in always-on volatile memory 330 and the remainder is stored in hibernation block 340.

Thus, in one embodiment, hibernation may be achieved using delta generation engine 320, whereby a base data version of part or all the controller's data is saved in non-volatile memory (such as flash), and at each DPD cycle, the difference between the base data (as saved in non-volatile memory) and the current data (and currently stored in the volatile memory subject to hibernation) is calculated and saved. As discussed in more detail below, the difference may be saved in volatile memory (such as in SRAM), in non-volatile memory (such as in flash memory), or in both volatile memory and non-volatile memory. In a specific embodiment, the difference may be saved in volatile memory unless the size of the difference is too large for volatile memory to accommodate. In that instance, a remainder of the difference (the amount of the difference that is too large to store in SRAM) is saved in non-volatile memory (such as flash). By using this approach for DPD mode, the controller 102 may turn off nearly all of the data SRAM in DPD mode, while still supporting short enter and exit times, and lower impact on flash endurance.

In operation, the data stored in volatile memory subject to hibernation has certain characteristics including: being a very large amount of data (e.g., the firmware data structures are very large); and having very few changes between hibernation cycles (e.g., the amount of modifications to the firmware data structures between DPD cycles is relatively small). The hibernation circuitry 310 may save a base data copy, and upon each DPD cycle, only differences (e.g., ‘delta’) between the base data and the current data are identified and saved and then used for re-constructing the data when exiting DPD, as discussed in more detail below. In this way, the firmware data structures can maintain their state and quickly recover on DPD wake-up.

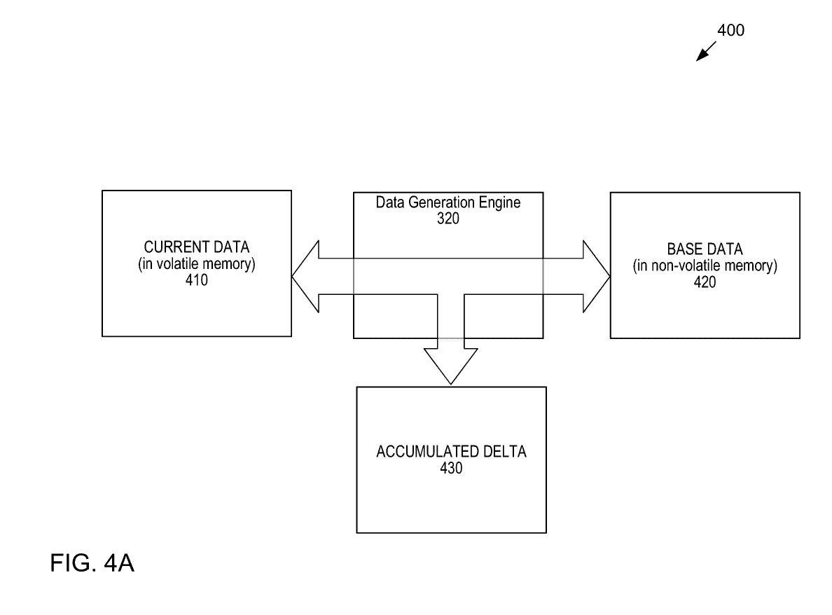

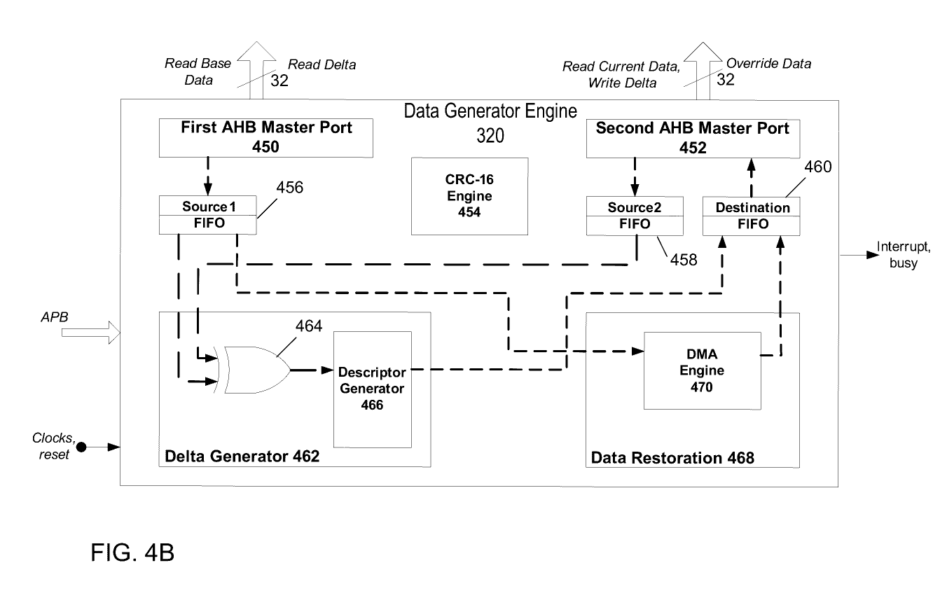

FIG. 4A illustrates a block diagram 400 of the data generation engine 320 in generating, with the current data, the base data and the accumulated delta, and in recreating the current data. As discussed above, the data generation engine 320 may generate the base data in response to one of several triggers. In one embodiment, the data generation engine 320 may generate, on the first DPD cycle, a base version of the data. On subsequent DPD cycles, the data generation engine 320 may compute the delta by reading and comparing the base data against the recent data (e.g., data that is currently stored in the section of memory subject to hibernation), and the delta is stored in always-on volatile memory 330. As discussed above, when the size of delta becomes too large (e.g., is larger than a threshold), or when a new hibernation block has to be allocated, the data generation engine 320 may generate a new base data version to save in hibernation block 340.

In one embodiment, when generating the delta, the base data and the current data are fetched and compared using a dedicated XOR engine which assists in finding the differences in the data.

FIG. 4B illustrates another block diagram of the data generation engine 320. In one embodiment, the data generation engine 320 is a high performance HW accelerator block that assists the FW to enter and exit DPD mode faster. Before the entrance to DPD mode, a delta is computed by fetching and comparing the base data against the current data, and is stored in always-on RAM. Upon exiting DPD mode, the recent data is restored using the generated delta and the base data.

The data generation engine 320 may use standard buses, such as advanced peripheral bus (APB) or advanced high-performance bus. Further, as illustrated in FIG. 4B, the data generation engine 320 may include two 32 bit AHB interfaces for fetching and writing data from/to the memories. The data generation engine 320 may also have an APB bus used by the FW to access the FW registers. In addition, the data generation engine 320 may include an interrupt line for notifying the FW through the interrupt controller about important events. Finally, the data generation engine 320 may include a busy signal which may be used by the Dynamic Power Manager in order to gate the data generation engine input clock when in idle state.

The data generation engine 320 may be triggered by the FW, which may activate either delta generator 462 or data restoration engine 468. In one embodiment, delta generator engine 462 and data restoration engine 468 do not work simultaneously.

Delta generator engine 462 fetches the base data via the first AHB master port 450 and the current data through the second AHB master port 452. Using this information, a delta is computed and stored in the memory using the second AHB master port 452.

Data restoration engine 468 fetches the delta via the first AHB master port 450 and, using this information, restores and stores the recent data in the memory using the second AHB master port 452.

The data generation engine 320 may calculate, using CRC-16 engine 454, the CRC-16 on the current data while generating the delta. In addition, there may comprise a special mode whereby the block may simply generate the CRC-16 based on the input data.

The data generation engine 320 may further incorporate the following sub-blocks: AHB Port (including first AHB master port 450 and the second AHB master port 452); FIFO (including source1 FIFO 456, source2 FIFO 458, and destination FIFO 460); delta generator engine 462; data restoration engine 468; and CRC-16 engine 454.

The AHB port is logic that implements the AHB protocol. It may be used to send read and written transactions to the memory or to the ASIC interconnect. The AHB port may provide a simple interface to the requesters for sending read and write requests. It may implement all of the required logic aligned with the AHB protocol. Upon completion, it updates the requester. In one embodiment, the AHB port may support back-to-back single read and write transactions.

When AHB error occurs, an error interrupt may be asserted. The data generation engine 320 may capture the address that caused this error in order to ease the debug process. In order to recover from this error scenario, FW may reset the data generation engine 320 may.

The generic AHP block may be instantiated twice, a single instance for each AHB master port 450 and 452.

The FIFO is logic that is used to temporarily store the data. It may be instantiated three times in the data generation engine 320. The first instance (source1 FIFO 456) is used for storing the fetch data from the first AHB master port 450. The second instance (source2 FIFO 458) is used for storing the fetch data from the second AHB master port 452. The third instance (destination FIFO 460) is used for storing the data that is going to be written to the memory using the second AHB master port 452.

Delta generator engine 462 is configured to generate the delta. This logic may be triggered by the FW after configuring all the needed parameters. The base data and the current data may be fetched from the memories data word by data word, and using a 32 bit XOR logic the input data is compared. In one embodiment, a data word is 32 bits such that a line size is 32 bits. Other sizes of data words are contemplated. A segment descriptor may be generated for each chunk of differences and stored in the delta memory. Upon completion, the FW is notified with all the relevant required information.

Data restoration engine 468 is configured to restore the recent data. This logic may be triggered by the FW after configuring all the needed parameters. The entire delta is fetched from the delta memory and, using this information, data restoration engine 468 restores and stores the recent data in the memory. Data restoration engine 468 may assume that the base data is stored in the output memory and it only overrides the modified DW. Upon completion, the FW is notified with all the relevant required information.

The CRC-16 engine 454 is responsible for calculating the CRC-16 over the input data. The CRC-16 engine 454 is automatically enabled while generating the delta. There may be a special mode when the FW may configure the data generation engine 320 to just calculate the CRC-16 over the input data.

The CRC-16 engine 454 may be used to ensure that the correct data has been restored. The CRC-16 calculation may be automatically performed over the current data while generating the delta. The CRC-16 result may further be stored in a FW register so the FW can obtain this value. For the data restoration (discussed in detail below), the CRC-16 engine 454 need not be active since the DGE 320 works on part of the data (e.g., delta) and not on the entire data. However, the FW may send a request to the DGE 320 to calculate the CRC-16 over the input data which is provided by the FW. In this regard, for the data restoration, the DGE 320 may be triggered twice. In the first iteration, the DGE 320 restores the current data using the delta memory while in the second iteration, the DGE may be triggered to fetch the entire restored data in order to calculate the CRC-16.

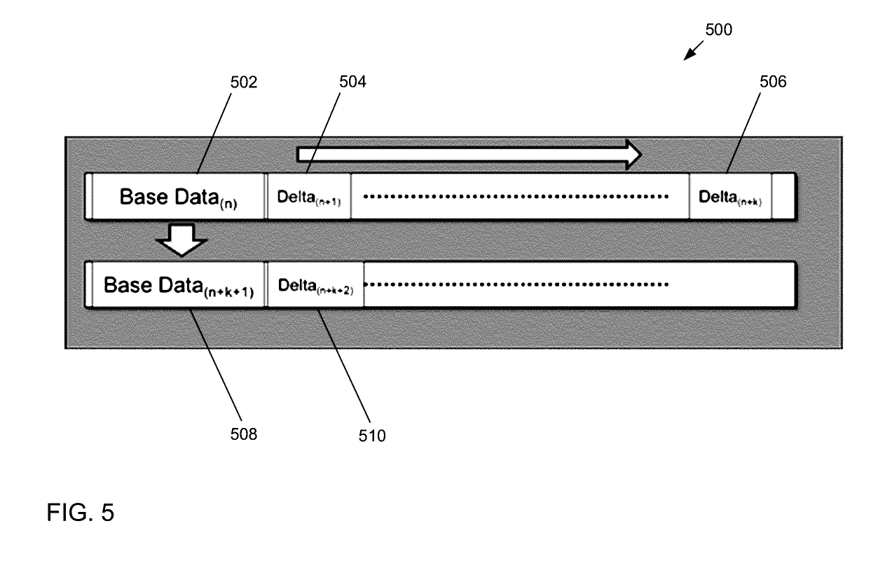

FIG. 5 illustrates a sequence 500 of base datas and accumulated deltas stored over time. Base data₍ₙ₎ 502 is stored in the memory device, such as in hibernation block 340, with n being a representation of the number of DPD cycles. Base data₍ₙ₎ 502 may be stored in response to one or more triggering events. As one example, on the first DPD cycle, a base version of the data is saved in an allocated hibernation SLC block (such as hibernation block 340). On subsequent DPD cycles, a delta is computed by reading and comparing the base data against the recent data, and the delta is saved. This is illustrated in FIG. 5 as Delta₍ₙ₊₁₎ (504) to Delta₍ₙ₊ₖ₎ (506). As illustrated in FIG. 5, at the n+k+1 DPD cycle, a new base data is stored (Base data₍ₙ₊ₖ₊₁₎ 508). Various conditions may trigger generation and storage of a new base data. For example, when the size of the delta is too large (e.g., Delta₍ₙ₊ₖ₎ (506) is greater than a threshold), and/or when a new block for storage of the base data is to be allocated, a new base data version is saved. Thereafter, in subsequent DPD cycles, such as n+k+2 DPD cycle, a delta is computed, such as Delta₍ₙ₊ₖ₊₂₎ (510).

As discussed above, delta is a measure of the difference between the base data and the current data as stored in the volatile memory. In particular, DGE 320 may scan the base data and current data, data word by data word, until a difference has encountered. Then, DGE 320 may find the location of the last mismatch in this chunk while updating the mismatched data in the delta memory skipping the location of the delta segment header. Next, a delta segment header may be generated containing the number of matched data words and the number of mismatched data words in this segment. As a result, the delta segment data may be located immediately after the header in the delta memory, although it may be written first. Then, DGE 320 may continue the scanning until the end of the base data/current data or the delta memory has reached.

Thus, for each chunk of mismatch in the current data and the base data, a delta segment may be generated. Further, each delta segment may be composed of two parts: delta segment header; and delta segment data.

By way of example, the delta segment header may contain two fields: EQ_LINE and DIFF_LINE. EQ_LINE contains the number of equal DWs passed from the last mismatched line. DIFF_LINE contains the number of mismatched data words in this delta segment.

The delta segment data may contain DIFF_LINE lines of mismatched data when DIFF_LINE is specified in the two least significant bits (LSB) of the segment header.

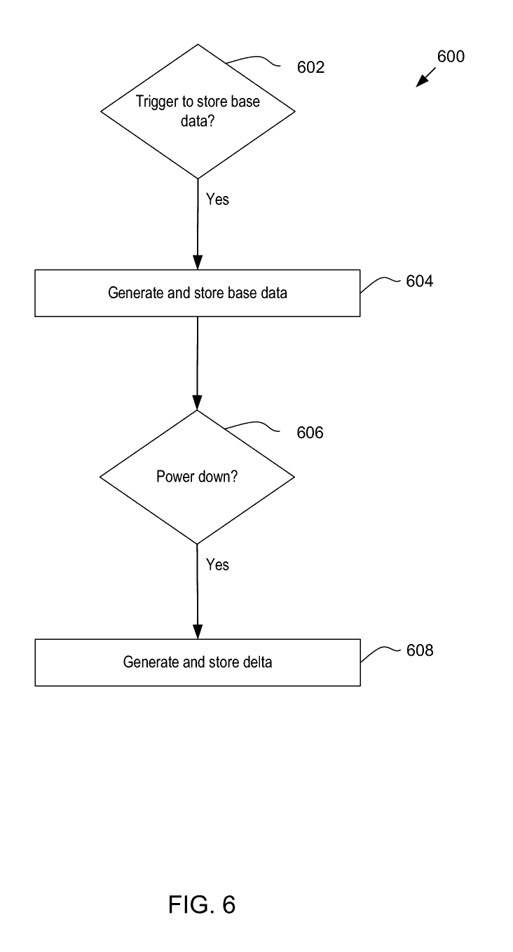

FIG. 6 illustrates a flow chart 600 for determining whether to store the base data and whether to store the delta. At 602, it is determined whether to trigger the storage of the base data. As discussed above, there are various triggers to store the base data, such as analysis of one or both of the delta and the base data, and such as whether the block storing the base data is to be erased. In response to determining that there is a trigger to store the base data, at 604, the base data is generated and stored. As discussed above, the base data may be the values (compressed or uncompressed) stored in the section of volatile memory subject to potential power loss.

In an alternative embodiment, the memory device does not generate any base data, instead relying on static pre-stored base data in ROM.

At 606, it is determined whether a power down for the section of volatile memory will occur. As discussed above, the host device may send a power down command to the memory device. In response to determining that a power down for the section of volatile memory will occur, at 608, the delta is generated and stored. As discussed above, the generate delta circuitry 322 may generate the delta, which may represent a difference between the base data and the current data stored in the section of volatile memory subject to power down.

In a more specific embodiment, the following steps may be performed when activating the delta generator engine 462:

1. initiate the base data in the memory.

2. ensure that the DGE Command Status0 register is configured (e.g., DGE_CMD_STAT0[READY] bit is set).

3. configure the pointer to the base data memory using the DGE_BASE_DATA_PTR register.

4. initiate the current data in the memory.

5. configure the pointer to the current data memory using the DGE_CURR_DATA_PTR register.

6. configure the pointer to the output delta memory using the DGE_DELTA_MEM_PTR register.

7. configure the size of the base data/current data memory using the DGE_SRC_DATA_SIZE register.

8. configure the size of the delta memory using the DGE_DELTA_MEM_SIZE register.

9. trigger the DGE 320 by setting a field in the DGE Command register (e.g., DGE_COMMAND[CMD]).

10. poll the DGE_CMD_STAT0[READY] bit until it is set by the HW or alternatively wait for OP_DONE interrupt assertion.

11. optionally, clear the interrupt event by setting DGE_IRQ_STATUS[OP_DONE] bit.

12. check if the last operation has completed successfully using the DGE_CMD_STAT0[OODM] bit. If so, re-activate the DGE for the rest of the data using the information captured in the DGE_CMD_STAT1 register.

13. read the CRC-16 output using the DGE_CMD_STAT2 register.

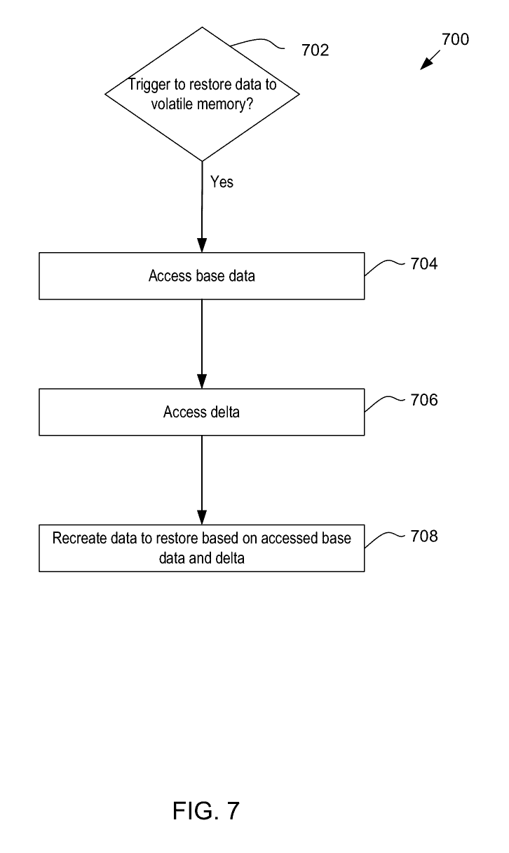

FIG. 7 illustrates a first flow chart 700 for determining whether and how to restore data previously stored in volatile memory. At 702, it is determined whether there is a trigger to restore the data to volatile memory. As discussed above, the host device may send a command to the memory device to exit DPD mode and re-enter normal mode.

In response to determining that the trigger to restore the data to the volatile memory has been received, at 704, the base data is accessed. Further, at 706, the delta is accessed. Though FIG. 7 shows that the base data is first accessed and then the delta is accessed, in an alternate embodiment, the converse may be performed. At 708, using the accessed base data and delta, the data is recreated to restore to the volatile memory.

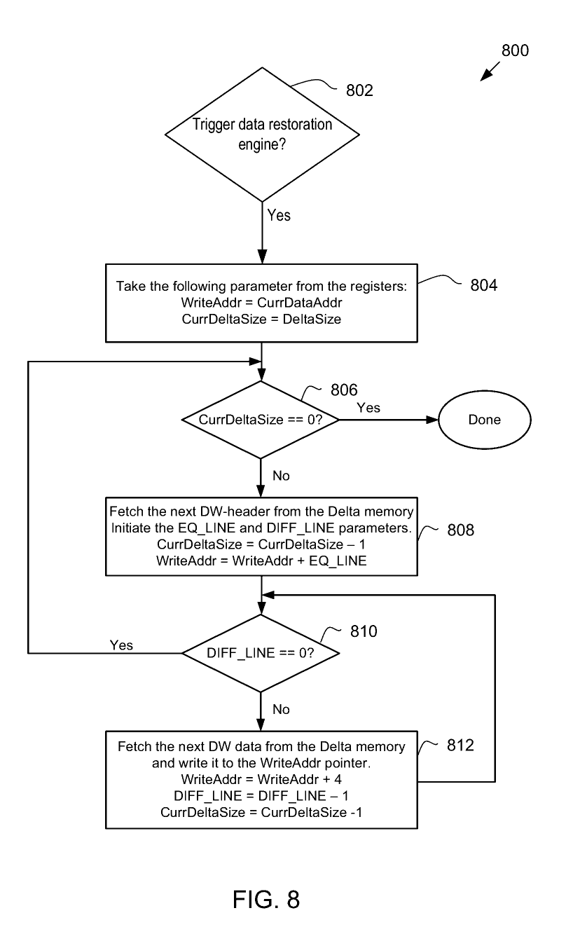

FIG. 8 illustrates a second flow chart 800 for determining whether and how to restore data previously stored in volatile memory. The DGE 320 may scan the delta memory segment be segment. For each delta segment, the DGE 320 may calculate the next write address and the number of mismatch lines using the delta segment header. The DGE 320 may then copy the Delta segment data to the appropriate location in the current data. When the entire iteration is done, the FW may be informed.

At 802, it is determined whether there is a trigger for the data restoration engine 468. As discussed above, the host device may send a command to the memory device to exit DPD mode and re-enter normal mode.

At 804, in preparation of the write, parameters are taken from certain registers including: WriteAddr=CurrDataAddr and CurrDeltaSize=DeltaSize. At 806, it is determined whether all of the entire delta has been reviewed (e.g., whether the CurrDeltaSize is equal to 0). If yes, the flow diagram 800 is done. If not, at 808, the next data word header is fetched from the delta memory and the EQ_LINE and DIFF_LINE parameters are initiated. Further, the pointers are adjusted, with the CurrDeltaSize is decremented and the WriteAddr pointing to the next line (e.g., WriteAddr+EQ_LINE).

At 810, it is determined whether the DIFF_LINE equals zero. If DIFF_LINE equals zero, this means that there are no more mismatched data words in the particular delta segment. If DIFF_LINE does not equal zero, this means that there are more mismatched data words in the particular delta segment. If so, at 812, the next data word data is fetched from the delta memory and written to the WriteAddr pointer. Further, the WriteAddr pointer is incremented, the DIFF_LINE is decremented (indicating one less mismatched data word), and the CurrDeltaSize is decremented (indicating review of another part of the delta has been reviewed). 812 loops back to 810 until the DIFF_LINE equals zero.

In a more specific embodiment, the following steps may be performed when activating the data restoration engine 468:

1. initiate the base data in the current data memory.

2. check the DGE Command Status0 register to ensure that the DGE_CMD_STAT0[READY] bit is set.

3. configure the pointer to the current data memory using the DGE_CURR_DATA_PTR register.

4. configure the pointer to the input Delta memory using the DGE_DELTA_MEM_PTR register.

5. configure the size of the Delta memory using the DGE_DELTA_MEM_SIZE register.

6. trigger data restoration engine 468 by writing to the DGE_COMMAND[CMD] field.

7. poll the DGE_CMD_STAT0[READY] bit until it is set by the HW or alternatively wait for OP_DONE interrupt assertion.

8. optionally, clear the interrupt event by setting DGE_IRQ_STATUS[OP_DONE] bit.

In one embodiment, data restoration may be performed using a direct memory access (DMA) operation. In particular, the DGE 320 may support a DMA operation in which the FW may provide the transfer size, source and destination addresses and the DGE 320 copies the data from the source memory to the destination memory. In one embodiment, this operation may be achieved by a special configuration of the data restoration engine 468. The FW may initiate the source data in the delta memory. In one embodiment, the size of the delta memory equals to the transfer length.

In order to activate a basic DMA operation where the data is copied from the source address to a destination address, the data restoration engine 468 may be activated in special way. The delta memory contains the source data and the transfer length is the size of the delta memory.

In one embodiment, the FW performs the following steps while activating the data restoration engine 468 for a basic DMA operation (e.g., up to a transfer of 65535 KB):

1. ensure that the DGE_CMD_STAT0[READY] bit is set.

2. configure the pointer to the destination data memory using the DGE_CURR_DATA_PTR register.

3. initiate the delta memory with the source data.

4. configure the pointer to the input delta memory using the DGE_DELTA_MEM_PTR register.

5. configure the size of the delta memory using the DGE_DELTA_MEM_SIZE register such that the size equals the transfer size.

6. trigger the data restoration engine 468 in DMA mode by setting a field in the DGE_COMMAND[CMD].

7. poll the DGE_CMD_STAT0[READY] bit until it is set by the HW or alternatively wait for OP_DONE interrupt assertion.

8. optionally, clear the interrupt event by setting DGE_IRQ_STATUS[OP_DONE] bit.

In the present application, semiconductor memory devices such as those described in the present application may include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

In one embodiment, a module may be used and may take the form of a packaged functional hardware unit designed for use with other components, a portion of a program code (e.g., software or firmware) executable by a (micro)processor or processing circuitry that usually performs a particular function of related functions, or a self-contained hardware or software component that interfaces with a larger system, for example.

Further, the methods, devices, processing, circuitry, and logic described herein may be implemented in many different ways and in many different combinations of hardware and software. For example, all or parts of the implementations may be circuitry that includes an instruction processor, such as a Central Processing Unit (CPU), microcontroller, or a microprocessor; or as an Application Specific Integrated Circuit (ASIC), Programmable Logic Device (PLD), or Field Programmable Gate Array (FPGA); or as circuitry that includes discrete logic or other circuit components, including analog circuit components, digital circuit components or both; or any combination thereof. The circuitry may include discrete interconnected hardware components or may be combined on a single integrated circuit die, distributed among multiple integrated circuit dies, or implemented in a Multiple Chip Module (MCM) of multiple integrated circuit dies in a common package, as examples.

Accordingly, the circuitry may store or access instructions for execution, or may implement its functionality in hardware alone. The instructions may be stored in a tangible storage medium that is other than a transitory signal, such as a flash memory, a Random Access Memory (RAM), a Read Only Memory (ROM), an Erasable Programmable Read Only Memory (EPROM); or on a magnetic or optical disc, such as a Compact Disc Read Only Memory (CDROM), Hard Disk Drive (HDD), or other magnetic or optical disk; or in or on another machine-readable medium. A product, such as a computer program product, may include a storage medium and instructions stored in or on the medium, and the instructions when executed by the circuitry in a device may cause the device to implement any of the processing described above or illustrated in the drawings.

The implementations may be distributed. For instance, the circuitry may include multiple distinct system components, such as multiple processors and memories, and may span multiple distributed processing systems. Parameters, databases, and other data structures may be separately stored and managed, may be incorporated into a single memory or database, may be logically and physically organized in many different ways, and may be implemented in many different ways. Example implementations include linked lists, program variables, hash tables, arrays, records (e.g., database records), objects, and implicit storage mechanisms. Instructions may form parts (e.g., subroutines or other code sections) of a single program, may form multiple separate programs, may be distributed across multiple memories and processors, and may be implemented in many different ways. Example implementations include stand-alone programs, and as part of a library, such as a shared library like a Dynamic Link Library (DLL). The library, for example, may contain shared data and one or more shared programs that include instructions that perform any of the processing described above or illustrated in the drawings, when executed by the circuitry.

Thus, associated circuitry may be used for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three dimensional exemplary structures described but cover all relevant memory structures within the spirit and scope of the invention as described herein and as understood by one of skill in the art.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the preferred embodiments described herein can be used alone or in combination with one another.

What is claimed is:

1. A method of recreating data stored in a section of volatile memory subject to power down, the method comprising:
determining to power down the section of volatile memory;
in response to determining to power down the section of volatile memory:
accessing a data set;
generating a representation of the data as stored in the section of volatile memory at a first time, the representation indicative of a difference between the accessed data set and the data as stored in part or all of the section of volatile memory at the first time;
storing the representation of the data;
determining, at a second time different from the first time, to recreate the data as stored in the section of memory at the first time; and
in response to determining to recreate the data as stored in the section of memory at the first time, using the data set and the representation in order to recreate the data as stored in the section of memory at the first time.

2. The method of claim 1, further comprising:
generating the data set at a time prior to the first time; and
storing the data set.

3. The method of claim 2, wherein the data set comprises a complete representation of the data as stored in the section of volatile memory at the time prior to the first time.

4. The method of claim 3, further comprising determining whether to generate a new data set at a time after the second time.

5. The method of claim 4, wherein determining whether to generate the new data set is based on analysis of the representation of the data.

6. The method of claim 5, wherein a size of the representation of the data is compared to a size of the data set to determine whether to generate the new data set.

7. The method of claim 1, wherein the representation of the data is stored in always-on volatile memory.

8. A memory device comprising:
power down determination circuitry configured to determine whether to power down a section of volatile memory;
delta generator circuitry configured, in response to determining to power down the section of volatile memory, to generate a delta between a stored data set and data stored in part or all of the section of volatile memory;
power up determination circuitry configured to determine to power up at least a part of the memory device; and
data restore circuitry configured, in response to determining to power up, to restore, using the delta and the stored data set, the data.

9. The memory device of claim 8, further comprising data set generation circuitry configured to generate the data set.

10. The memory device of claim 9, wherein the delta generate circuitry is configured to generate the delta between the stored data set and the data as stored in the section of volatile memory at a first time; and
wherein the data set generation circuitry is configured to store at least a part of the data stored in the section of volatile memory at a time prior to the first time.

11. The memory device of claim 10, wherein the data set generation circuitry is configured to store all of the data stored in the section of volatile memory at the time prior to the first time; and
wherein the delta generator circuitry is configured to generate a difference between all of the data stored in the section of volatile memory at the time prior to the first time and all of the data stored in the section of volatile memory at the first time.

12. The memory device of claim 9, further comprising data set re-generation circuitry configured to re-generate the data set.

13. The memory device of claim 12, wherein the data set re-generation circuitry is configured to determine whether to re-generate the data set based on analysis of the delta.

14. The memory device of claim 13, wherein the data set re-generation circuitry is configured to:
compare a size of the stored data set to a size of the delta; and
determine, based on the comparison, to re-generate the data set by storing all of the data in the section of volatile memory.

15. A method of recreating data stored in a section of volatile memory subject to power down, the method comprising:
storing data, the data being based on data as stored in the section of volatile memory at a first time;
determining to power down the section of volatile memory;
in response to determining to power down the section of volatile memory:
generating, at a second time different from the first time, a representation of the data as stored in the section of volatile memory at the second time, the representation being based on the stored data;
storing the representation of the data;
determining, at a third time, to recreate the data as stored in the section of memory at the second time, wherein the third time is different from and after the first time and the second time;
in response to determining to recreate the data as stored in the section of memory at the second time:
accessing the stored data;
accessing the representation of the data;
recreating the data as stored in the section of volatile memory at the second time based on the accessed representation of the data and the accessed stored data.

16. The method of claim 15, wherein the stored data comprises a complete representation of the data as stored in the section of volatile memory at the first time.

17. The method of claim 16, wherein the representation of the data comprises a difference between the stored data and the data as stored in the section of volatile memory at the second time.

18. The method of claim 17, wherein, in response to determining to recreate the data as stored in the section of memory at the second time, accessing the complete representation and the difference in order to recreate the data as stored in the section of volatile memory at the second time.

19. The method of claim 15, wherein the data is stored in non-volatile memory; and
wherein the representation of the data is stored, at least partly, in volatile memory not subject to power down.

20. The method of claim 19, wherein the volatile memory not subject to power down comprises always-on volatile memory; and
wherein part of the representation of the data is stored in the always-on volatile memory and a remainder is stored in non-volatile memory.

21. The method of claim 15, wherein the memory device determines to power down at multiple separate times; and
for each of the multiple separate times:
in response to determining to power down, storing a representation of the data as a delta indicative of the difference between the stored data and the data as stored in the section of volatile memory at the respective time; and
in response to determining to recreate the data as stored in the section of memory at the respective time:
accessing the stored data;
accessing the delta indicative of the difference between the stored data and the data as stored in the section of volatile memory at the respective time; and
recreating the data as stored in the section of memory at the respective time based on the accessed complete representation and the accessed delta.
